(19) United States
(12) Patent Application Publication
(10) Pub. No.: US 2025/0043213 A1
(43) Pub. Date: Feb. 6, 2025

(54) CLEANING FORMULATION

(71) Applicant: Dow Global Technologies LLC, Midland, MI (US)

(72) Inventors: Qi Jiang, Shanghai (CN); Edward D. Daugs, Midland, MI (US); Meijia He, Shanghai (CN)

(73) Assignee: Dow Chemical (China) Investment Company Limited, Shanghai (CN)

(21) Appl. No.: 18/718,877

(22) PCT Filed: Dec. 14, 2021
(86) PCT No.: PCT/CN2021/137779

§ 371 Date: Jun. 12, 2024

(51) Int. Cl. C11D 3/20; C11D 3/30; C11D 17/00

(52) U.S. Cl. CPC C11D 3/2068; C11D 3/30; C11D 17/0008; C11D 2111/22; C11D 2111/46

(57) ABSTRACT

A glycol ether-containing water-based composition useful for cleaning contaminants present on the surface of a substrate, such as the surface of a printed circuit board during the manufacturing process of the printed circuit board, the contaminants including for example, solder flux and photoresist on the printed circuit board; the glycol ether-containing water-based composition including: (a) at least one glycol ether having a high boiling point and a low VOC; (b) at least one organic amine; (c) at least one surfactant; and (d) water; a process for producing the above glycol ether-containing water-based composition; and a process for cleaning a printed circuit board using the above glycol ether-containing water-based composition.

### FIELD

The present invention relates to a cleaning formulation, and more specifically, the present invention relates to a glycol ether-containing water-based composition which can be used as a cleaning formulation in electronic processing applications, for example, to clean solder flux and photoresist during printed circuit board manufacturing.

### BACKGROUND

The manufacture of printed circuit boards (PCBs) requires multiple procedures, including essential cleaning steps. In current cleaning formulations, low molecular weight solvents are broadly used as cleaning agents. These solvents are considered volatile organic compounds, or VOCs, due to their low molecular weights and corresponding low boiling points. With increasing environmental protection regulations, a safer, halogen-free, non-VOC or low-VOC solvent is requested by the printed circuit board (PCB) industry for use in cleaning formulations. Besides the VOC content, the ability of the solvent to effectively clean the substrate and to provide a high solvent purity (colorless, with a low residue content and low impurity profile) are also requested criteria of the solvents provided to the PCB industry.

PCB cleaning formulations and ingredients are well-known in the electronics industry. For example, various flux removal cleaning formulations are mentioned in JP04776710B2, JP06458964B2, JP05945914B2, JP2003064397A, U.S. Pat. No. 7,288,511B2, U.S. Pat. No. 6,689,734B2, U.S. Pat. No. 5,547,601A, CN111171974A, CN110373283A, CN109837145A, CN103013704A, and WO1993016160A1. Also known in the art are various photoresist cleaning formulations for removing photoresist from PCBs, for example, as mentioned in JP04570786B2, U.S. Pat. No. 7,579,308B2, U.S. Pat. No. 7,288,511B2, U.S. Pat. No. 6,689,734B2, CA1285463C, and CN107942624A. In addition, U.S. Pat. No. 8,444,768B2 mentions a cleaning formulation used in flux removal and PCB cleaning. The cleaning formulation of U.S. Pat. No. 8,444,768B2 consists 40-97 wt. % solvents including glycol ethers, 2-60 wt. % additives including acid-based surfactant and amines (e.g., alkanolamine). The formulation of U.S. Pat. No. 8,444,768B2 is diluted with water, acetone, or alcohol.

It would be desirable to have new cleaning formulations having desirable properties for use in cleaning applications such as use by the PCB industry for cleaning PCBs.

### SUMMARY

The present invention is directed to glycol ether-containing water-based (GEWB) cleaning formulations which can be used for effectively cleaning solder flux and photoresist during PCB manufacturing. The GEWB cleaning formulations can provide good dissolution of solutes including rosin flux and phenolic photoresist.

In some embodiments of the present invention, the GEWB cleaning formulation for cleaning solder flux and photoresist during the manufacturing process of PCBs includes a GEWB cleaning formulation comprising: (a) at least one glycol ether; (b) at least one organic amine; (c) at least one surfactant; and (d) water.

Other embodiments of the present invention include processes for preparing the above-described GEWB composition.

In still other embodiments, the present invention includes a cleaned PCB prepared by contacting a non-cleaned PCB containing a first amount of contaminants thereon with the above-described GEWB cleaning formulation to reduce the amount of contaminants on the non-cleaned PCB to a second reduced amount of contaminants; and thus, forming a cleaned PCB containing a low level of contaminants thereon.

### DETAILED DESCRIPTION

Specific embodiments of the present application are described herein below. These embodiments are provided so that this disclosure is thorough and complete and fully conveys the scope of the claimed subject matter of the present invention to those skilled in the art.

Unless stated to the contrary or otherwise, implicit from the context, or customary in the art, all percentages, parts, ratios, and the like amounts, are defined by, or based on, weight. Parts and percent values are based on weight. For example, all percentages stated herein are weight percentages (wt %), unless otherwise indicated. And, all test methods disclosed herein are current as of the filing date of this disclosure.

Temperatures used herein are in degrees Celsius (° C.).

“Room temperature (RT)” and “ambient temperature” herein means a temperature between 20° C. and 26° C., unless specified otherwise.

The term “composition,” as used herein, refers to a mixture of materials which comprises the composition, as well as reaction products and decomposition products formed from the materials of the composition.

“VOC” stands for volatile organic compound(s).

The term “low-VOC” content, with reference to an organic solvent such as a glycol ether, herein means the organic solvent has a boiling point of ≥250° C., a vapor pressure of <10 Pa at 20° C., and/or a GC elution of less than or equal to 20% of compounds at greater than the retention time of tetradecane (C14) as a GC elution retention time marker.

“Glycol ether-containing”, with reference to a water-based composition, herein means the dosage of glycol ether in the water-based composition is more than 0%.

“Water-based”, with reference to a diluted glycol ether-containing composition, herein means the dosage of water in the diluted glycol ether-containing composition is at least 50% or more.

A “high purity solvent” or “high solvent purity”, with reference to an organic solvent, herein means a solvent having a color value of less than APHA 100. Also, “colorless”, with reference to an organic solvent, herein means a solvent having a color value of less than 100 APHA.

“Low residue content”, with reference to an organic solvent, herein means a solvent having a residual base content of less than 0.01 wt % titrated as sodium hydroxide.

“Low impurity profile”, with reference to an organic solvent, herein means that a solvent comprises greater than 95% of the glycol ether oligomers.

The terms “comprising,” “including,” “having,” and their derivatives, are not intended to exclude the presence of any additional component, step or procedure, whether or not the same is specifically disclosed. In order to avoid any doubt, all compositions claimed through use of the term “comprising” may include any additional additive, adjuvant, or compound, whether polymeric or otherwise, unless stated to the contrary. In contrast, the term “consisting essentially of” excludes from the scope of any succeeding recitation any other component, step, or procedure, excepting those that are not essential to operability. The term “consisting of” excludes any component, step, or procedure not specifically delineated or listed. The term “or,” unless stated otherwise, refers to the listed members individually as well as in any combination. Use of the singular includes use of the plural and vice versa.

The numerical ranges disclosed herein include all values from, and including, the lower and upper value. For ranges containing explicit values (e.g., a range from 1, or 2, or 3 to 5, or 6, or 7), any subrange between any two explicit values is included (e.g., the range 1 to 7 above includes subranges 1 to 2; 2 to 6; 5 to 7; 3 to 7; 5 to 6; and the like.).

As used throughout this specification, the abbreviations given below have the following meanings, unless the context clearly indicates otherwise: “=” means “equal(s)” or “equal to”; “<” means “less than”; “>” means “greater than”; “≤” means “less than or equal to”; ≥” means “greater than or equal to”; “@” means “at”; ppm=parts per million; “MT”=metric ton(s); g=gram(s); mg=milligram(s); Kg=kilogram(s); L=liters; g/L=gram(s) per liter; μL=microliter(s); “g/cm³” or “g/cc”=gram(s) per cubic centimeter; mg/mL=milligrams per milliliter; “kg/m³=kilogram(s) per cubic meter; rpm=revolutions per minute; m=meter(s); mm=millimeter(s); cm=centimeter(s); μm=micron(s) or micrometer(s); nm=nanometer(s); min=minute(s); s=second(s); ms=millisecond(s); hr=hour(s); Pa=pascals; Mpa=megapascals; kPa=kilopascals; Pa-s=Pascal second(s); mPa-s=millipascal second(s); g/mol=gram(s) per mole(s); g/eq=gram(s) per equivalent(s); Mn=number average molecular weight; Mw=weight average molecular weight; pts=part(s) by weight; l/s or sec⁻¹=reciprocal second(s) [s⁻¹]; ° C.=degree(s) Celsius; ° C./min=degree(s) Celsius per minute; psi=pounds per square inch; kPa=kilopascal(s); %=percent; cal/mole=calorie(s)/mole; vol %=volume percent; mol %=mole percent; and wt %=weight percent.

Generally, the GEWB cleaning composition or formulation useful for cleaning solder flux and photoresist during the manufacturing process of PCBs, includes: (a) at least one or more glycol ethers. Exemplary of the glycol ethers that can be used are: triethylene glycol methyl ether, tetraethylene glycol methyl ether, pentaethylene glycol methyl ether, hexaethylene glycol methyl ether, heptaethylene glycol methyl ether, octaethylene glycol methyl ether, triethylene glycol ethyl ether, tetraethylene glycol ethyl ether, pentaethylene glycol ethyl ether, hexaethylene glycol ethyl ether, heptaethylene glycol ethyl ether, octaethylene glycol ethyl ether, triethylene glycol propyl ether, tetraethylene glycol propyl ether, pentaethylene glycol propyl ether, hexaethylene glycol propyl ether, heptaethylene glycol propyl ether, octaethylene glycol propyl ether, triethylene glycol butyl ether, tetraethylene glycol butyl ether, pentaethylene glycol butyl ether, hexaethylene glycol butyl ether, heptaethylene glycol butyl ether, octaethylene glycol butyl ether, tripropylene glycol methyl ether, tetrapropylene glycol methyl ether, pentapropylene glycol methyl ether, hexapropylene glycol methyl ether, heptapropylene glycol methyl ether, octapropylene glycol methyl ether, tripropylene glycol ethyl ether, tetrapropylene glycol ethyl ether, pentapropylene glycol ethyl ether, hexapropylene glycol ethyl ether, heptapropylene glycol ethyl ether, octapropylene glycol ethyl ether, tripropylene glycol propyl ether, tetrapropylene glycol propyl ether, pentapropylene glycol propyl ether, hexapropylene glycol propyl ether, heptapropylene glycol propyl ether, octapropylene glycol propyl ether, tripropylene glycol butyl ether, tetrapropylene glycol butyl ether, pentapropylene glycol butyl ether, hexapropylene glycol butyl ether, heptapropylene glycol butyl ether, octapropylene glycol butyl ether, and mixtures thereof.

In some preferred embodiments, the glycol ether can be, for example, (1) a mixture of two or more of the following components: tripropylene glycol propyl ether, tetrapropylene glycol propyl ether, pentapropylene glycol propyl ether, hexapropylene glycol propyl ether, heptapropylene glycol propyl ether, and octapropylene glycol propyl ether; or (2) a mixture of two or more of the following components: tripropylene glycol butyl ether, tetrapropylene glycol butyl ether, pentapropylene glycol butyl ether, hexapropylene glycol butyl ether, heptapropylene glycol butyl ether, and octapropylene glycol butyl ether.

In some embodiments, the glycol ether, component (a), of the present invention has a boiling point (at 101.3 kPa pressure and at 25° C. temperature) of from 250° C. to 350° C. in one general embodiment, from 250° C. to 300° C. in another embodiment, and from 250° C. to 280° C. in still another embodiment. The boiling point of the glycol ether can be determined using the method described in ASTM D1078-03.

The volatile organic compounds (VOC) of the glycol ether of the present invention can depend on various factors such as boiling point, vapor pressure, and molecular weight. EU directive 2004/42/EC defines VOCs as any organic compound with a boiling point of ≤250° C. at standard pressure; and VOC content is measured by GC analysis as per ISO 11890-2. A GC marker used to measure relative boiling points is tetradecane, which has a boiling point of 253.6° C. Based on the above method for determining VOC content, the criteria used herein to determine the VOC content of the glycol ether of the present invention is boiling point; and the glycol ether of the present invention has boiling points within the above-described ranges.

In some embodiments, the glycol ether, component (a), of the present invention has molecular weight (Mw) of from 170 to 550 in one general embodiment, from 180 to 500 in another embodiment, and from 190 to 490 in still another embodiment.

In some embodiments, the glycol ether, component (a), of the present invention has a hydroxyl number of from 220 to 320 in one general embodiment, from 250 to 300 in another embodiment, and from 270 to 285 in still another embodiment. The hydroxyl number of the glycol ether can be determined using the method described in ASTM D1899-02.

In some embodiments, the glycol ether, component (a) of the present invention, in general has: (1) a dispersion Hansen solubility parameter of from 13.0 J/cc^{1/2} to 15.5 J/cc^{1/2}; (2) a polarity Hansen solubility parameter of from 0.5 J/cc^{1/2} to 3.0 J/cc^{1/2}; and (3) a hydrogen-bonding Hansen solubility parameter of from 6.5 J/cc^{1/2} to 8.5 J/cc^{1/2} using the method described in the Examples herein below.

The concentration of the glycol ether present in the GEWB cleaning formulation can be from 1 wt % to 75 wt % in one broad embodiment. When the GEWB cleaning formulation is used, for example, as a photoresist cleaner, the glycol ether can be present in the photoresist cleaner in a concentration in the range of from 5 wt % to 50 wt % in one general embodiment, based on the total weight of all components in the composition; from 10 wt % to 40 wt % in another embodiment, and from 15 wt % to 30 wt % in still another embodiment. In other embodiments, when the GEWB cleaning formulation is used, for example, as a flux remover, the concentration of the glycol ether in the flux remover can be in the range of from 20 wt % to 70 wt % in one general embodiment, based on the total weight of all components in the composition; from 25 wt % to 60 wt % in another embodiment, and from 30 wt % to 50 wt % in still another embodiment.

Component (b) of the composition of the present invention is at least one pH modifier agent, for example, an organic amine-based pH modifier. For example, component (b), can include: monoethanolamine, diethanolamine, triethanolamine, monoisopropanolamine, dipropanolamine, tripropanolamine, β-aminoisobutyl alcohol, other similar alcohol amines, and mixtures thereof.

In one preferred embodiment, component (b) of the composition of the present invention comprises, consists essentially of, or consists of: a monoethanolamine, monoisopropanolamine, and mixtures thereof.

The organic amine, component (b), is advantageously used for modifying the pH of the GEWB cleaning formulation of the present invention; and the amount of the organic amine in the GEWB cleaning formulation should be sufficient to modify the pH of the formulation. For example, the concentration of the organic amine useful in the composition of the present invention can be from 1 wt % to 15 wt %, based on the total weight of all components in the composition, in one general embodiment, and from 3 wt % to 10 wt % in another embodiment.

Component (c) of the composition of the present invention is at least one surfactant. In some embodiments, the surfactant, component (c), can include an anionic surfactant, a cationic surfactant, and a nonionic surfactant, and mixtures thereof. For example, in some embodiments, the surfactant is an anionic surfactant such as at least one of dodecylbenzene sulfonate, diethanolamine oleate, triethanolamine oleate, triethanolamine dodecylbenzene sulfonate, ethanolamine lauryl sulfate, and mixtures thereof.

For example, in some embodiments, the surfactant is a nonionic surfactant such as at least one of a high alcohol polyoxyethylene ether, an alkylphenol polyoxyethylene ether, a fatty acid alkanolamide, a coconut oil fatty acid diethanolamide, and the like having a narrow distribution of HLB (hydrophilic-lipophilic balance) value between 10 and 14.

The advantages of adding the surfactant, component (c), into the composition of the present invention include, for example, (1) the surfactant increases the emulsification or dispersion of the solutes including photoresist, rosin, and solder flux; and increases the suspension and stability of the composition.

The concentration of the surfactant useful in the composition of the present invention can be from 0.01 wt % to 10 wt %, based on the total weight of all components in the composition, in one general embodiment, from 0.1 wt % to 8 wt % in another embodiment, and from 0.5 wt % to 5 wt % in still another embodiment.

Component (d) of the composition of the present invention is water. Any source of water can be used including, for example, tap water, deionized (DI) water; and the like; and mixtures thereof.

The amount (dosage) of water useful in the composition of the present invention for the function of diluting the glycol ether-containing composition, can be at least 50 wt % or more in one general embodiment; from 50 wt % to 99 wt % in another embodiment; from 50 wt % to 90 wt % in still another embodiment; from 50 wt % to 80 wt % in yet another embodiment; and from 50 wt % to 70 wt % in even still another embodiment, based on the total weight of all components in the composition.

Optionally, the composition of the present invention may be formulated with a wide variety of additives to enable performance of specific functions while maintaining the excellent benefits/properties of the present invention composition. For example, the optional additives, component (e), useful in the formulation of the present invention may be selected from corrosion inhibitors, water, antioxidants, and mixtures thereof.

In one preferred embodiment, as an optional additive, a corrosion inhibitor such as citric acid, lauric acid, and mixtures thereof, can be added to the composition of the present invention.

The optional compounds, when used in the composition of the present invention, can be present in an amount generally in the range of from 0 wt % to 0.1 wt % in one embodiment; from 0.01 wt % to 0.05 wt % in another embodiment; and from 0.01 wt % to 0.03 wt % in still another embodiment.

In one broad embodiment, the process for making the GEWB cleaning formulation of the present invention includes mixing, admixing or blending, for example: (a) at least one glycol ether; (b) at least one organic amine; (c) at least one surfactant; and (d) water; wherein a GEWB cleaning formulation is formed; and wherein the GEWB cleaning formulation has improved properties described herein below. One or more additional optional components, component (e), may be added to the formulation, if desired. For example, the components (a), (b), (c), and (d) can be mixed together in the desired concentrations discussed above and at a temperature of from 20° C. to 50° C. in one embodiment; and from 25° C. to 35° C. in another embodiment. If desired, the optional additives, component (e), can be mixed with any one or more of the components (a), (b) (c), and/or (d). The order of mixing of the components is not critical; and two or more components can be mixed together followed by addition of the remaining components. The formulation components may be mixed together by any conventional mixing process and equipment as known to those skilled in the art of mixing.

In other embodiments, the process for making the GEWB cleaning formulation of the present invention includes the steps of:
(I) providing at least one first glycol ether solvent having a contaminant content of greater than or equal to 1 weight percent and/or a color value of >100 APHA;
(II) purifying the at least one first glycol ether solvent to form at least one second purified glycol ether solvent having a color less than 100 APHA and having less than 0.01 wt % base titrated as sodium hydroxide;
(III) providing the following components: (a) the at least one purified second glycol ether from step (II) having a high boiling and low VOC; (b) at least one pH modifier component such as an organic amine; (c) at least one surfactant; and (d) water; and
(IV) mixing the components of step (III).

In step (II) of the above process, it is desired to remove as much sodium as possible so that the sodium will not form a residue on the surface of the electronic PCBs.

In step (III) of the above process, in some preferred embodiments, the at least one purified second glycol ether from step (II) has a boiling point of ≥250° C.; and has a low VOC, in terms of vapor pressure, of <10 Pa at 20° C.

After mixing the components (a)-(c) in step (IV) of the above process, the resultant GEWB cleaning formulation formed by the above process has good (increased) solubility of solute and good water solubility properties.

The GEWB cleaning formulation of the present invention, produced by the processes described above, has several advantageous properties and/or benefits compared to known formulations. For example, some of the properties/benefits exhibited by the present invention composition can include, for example: (1) the glycol ether, used to form the GEWB cleaning formulation of the present invention, is a water dilutable solvent which is a preferred component for producing cleaning formulations, particularly, when using water to dilute the formulation instead of other organic dilution chemicals; (2) the glycol ether has a high molecular weight (e.g., the carbon number of the glycol ethers are more than 9), for example the glycol ether of propoxylates of butanol and propanol, which provide a non-VOC composition or a low-VOC composition; (3) the GEWB cleaning formulation of the present invention does not contain hazardous components (e.g. halogen-based solvents) such monobrominated hydrocarbon; (4) the glycol ethers used in the GEWB cleaning formulation of the present invention has a cleaning function rather than an emulsion function; (5) the chemical structures of the GEWB cleaning formulation of the present invention are not complex and straightforward, (6) the glycol ether products have a broad higher molecular weight distribution and therefore are better because the glycol ether products are non-VOC; (7) the glycol ethers are initiated from alcohol structure rather than pure ethylene-oxide-based solvent; and therefore, the GEWB cleaning formulation of the present invention is better because the solubility of solute used in PCB processing is improved when using GEWB cleaning formulation of the present invention; and (8) a low residue of contaminants is formed on the PCB because the of the glycol ether; and if any residue is formed, the residue can be readily removed by rinsing the residue with water, alcohols, or ketones.

For example, the water solubility of the composition of the present invention, can be generally in the range of from 4 wt % to 90 wt % in one embodiment; from 20 wt % to 70 wt % in another embodiment; and from 30 wt % to 50 wt % in still another embodiment.

The cleaning formulation of the present invention can be used, for example, in electronics applications such as for cleaning electronic materials such as PCBs and other electronic elements including transistors, chips, and capacitors, conductive circuits, displays, amplifiers, and the like.

In a preferred embodiment, the GEWB formulation of the present invention can be used, for example, for cleaning solder flux and photoresist during the manufacturing process of PCBs. Various methods can be used for cleaning the PCBs such as a spraying method and an ultrasonic method which are known to those skilled in the art.

For example, in some embodiments, the process of cleaning PCBs using the GEWB cleaning formulation of the present invention can include a spraying method comprising the steps of:
(1) preparing the GEWB cleaning formulation;
(2) contacting a PCB with the GEWB cleaning formulation by spraying the GEWB cleaning formulation in liquid form;
(3) rinsing the PCB from step (2) with water; and
(4) drying the water rinsed PCB from step (3) at room temperature or at an elevated temperature.

For example, in other embodiments, the process of cleaning PCBs using the GEWB cleaning formulation of the present invention can include an ultrasonic method comprising the steps of:
(1) preparing the GEWB cleaning formulation;
(2) contacting a PCB with the GEWB cleaning formulation by placing the PCB in an ultrasonic bath of the GEWB cleaning formulation in liquid form;
(3) removing the PCB from step (2) from the ultrasonic bath;
(4) rinsing the PCB from step (3) with water; and
(5) drying the water rinsed PCB from step (4) at room temperature or at an elevated temperature.

Some of the advantages of a cleaned PCB of the present invention prepared by the above process of the present invention include, for example: (1) the cleaned PCB of the present invention has a longer working life compared to a non-cleaned PCB; (2) the cleaned PCB of the present invention cleaned with the process of the present invention using a low-VOC solvent has a working life that is longer than, or is the same as, a PCB cleaned with a conventional method using a solvent having a substantial content of VOC; (3) the cleaned PCB of the present invention has an increased working stability compared to a non-cleaned PCB; and (4) the cleaned PCB of the present invention cleaned with the process of the present invention using a low-VOC solvent has a working stability that is longer than, or is the same as, a PCB cleaned with a conventional method using a solvent having a substantial content of VOC. In some embodiments, the above advantages can be exhibited by a cleaned PCB of the present invention prepared by the process of the present invention even when the cleaned PCB of the present invention is compared to other cleaned PCBs prepared using a non-VOC content solvent.

### Examples

The following Inventive Examples (Inv. Ex.) and Comparative Examples (Comp. Ex.) (collectively, “the Examples”) are presented herein to further illustrate the features of the present invention but are not intended to be construed, either explicitly or by implication, as limiting the scope of the claims. The Inventive Examples of the present invention are identified by Arabic numerals and the Comparative Examples are represented by letters of the alphabet. The following experiments analyze the performance of embodiments of the compositions described herein. Unless otherwise stated all parts and percentages are by weight on a total weight basis.

### Designations

Various terms, designations and abbreviations used in the Examples are described herein as follows:

“PCB” stands for printed circuit board.

“MEA” stands for monoethanolamine.

“MPG” stands for methoxypolyethylene glycol.

“Refined”, with reference to a compound, means the compound has been subjected to a purification process such as distillation or evaporation to remove undesirable residuals for an original compound to reduce the contaminants present in the original compound to an amount of less than 0.01 wt %. For example, an MPG original product which has about 2 wt % of impurities and when the MPG is purified to reduce the original amount of impurities to less than 0.01 wt %, the resultant product is referred to as “MPG Refined”.

“BPG” stands for butoxypolyethylene glycol.

“BPG Refined” means a butoxypolyethylene glycol product having an undesirable residual base content of less than 0.01 wt % and such that the APHA of the refined/purified butoxypolyethylene glycol n-propyl ether product is less than 100.

“PolyPnB” stands for polypropylene glycol n-butyl ether.

“PolyPnB Refined” means a polypropylene glycol n-butyl ether product having an undesirable residual base content of less than 0.01 wt % and such that the APHA of the refined/purified polypropylene glycol n-butyl ether product is less than 100.

“PolyPnP” stands for polypropylene glycol n-propyl ether.

“PolyPnP Refined” means a polypropylene glycol n-propyl ether product not having an undesirable residual base content of less than 0.01 wt % and such that the APHA of the refined/purified polypropylene glycol n-propyl ether product is less than 100.

### Raw Materials

Table I describes the raw materials (ingredients) including the glycol ether, the organic amine and the surfactant, used in the Examples to prepare the GEWB cleaning formulation for cleaning solder flux and photoresist during the manufacturing process of PCBs.

TABLE I
Ingredients

| Product | Brief Description | | |
|---|---|---|---|
| (Ingredient) | of Product | Purity | Supplier |
| PolyPnP | Polypropylene | Mixture | The Dow |
| | glycol propyl ether | | Chemical |
| | | | Company |
| | | | (TDCC) |
| PolyPnB | Polypropylene | Mixture | TDCC |
| | glycol butyl ether | | |
| MEA | Monoethanolamine | >=99.0 wt % | TDCC |
| ECOSURF ™ EH-6 | Alkoxylated | >=99.0 wt % | TDCC |
| | 2-ethylhexenol | | |
| DOWANOL ™ DPnB | Dipropylene | >=99.0 wt % | TDCC |
| | glycol butyl ether | | |
| DOWANOL ™ TPnB | Tripropylene | >=99.0 wt % | TDCC |
| | glycol butyl ether | | |
| Polyglycol P-425 | Polypropylene | >=99.0 wt % | TDCC |
| | glycol (Mw. 425) | | |
| Hexyl CARBITOL ™ | Diethylene glycol | >=99.0 wt % | TDCC |
| | hexyl ether | | |
| MPG | Polyethylene | Mixture | TDCC |
| | glycol methyl ether | | |
| BPG | Polyethylene | Mixture | TDCC |
| | glycol butyl ether | | |
| Rosin | C₁₉H₂₉COOH | >=99.0 wt % | SCRC |
| Brand: BS-10 | Solder Flux | Mixture | Goot |
| Photoresist | Phenolic-based | >=99.0 wt % | Huntsman |

### Volatile Organic Compounds (VOC) Content

Depending on the particular application and the region where a solvent is used, solvent content in formulations is constrained by the volatile organic compounds (VOC) content, which comes under a variety of different environmental regulations throughout the world. These evolving regulations are aimed at improving both indoor and outdoor air quality control. There are several definitions of VOCs, because volatility depends on factors such as boiling point, vapor pressure, and molecular weight. EU directive 2004/42/EC defines VOCs as any organic compound with a boiling point of ≤250° C. at standard pressure; and VOC content is measured by GC analysis as per ISO 11890-2. A GC marker used to measure relative boiling points is tetradecane, which has a boiling point of 253.6° C.

A customized UIC RFT-6 laboratory rolled or wiped film evaporator (WFE) was used to prepare refined glycol ethers. The 0.06 square meter internal evaporative area 316 stainless steel evaporator was set at the desired processing temperature, and placed under vacuum. The feed material to the WFE was loaded using a Mahr Feinprüf Model N19 0.6 spinning pump which feeds at a rate of 0.66 cc/revolution. Vapor exiting the evaporator section was condensed on a tap water-cooled 0.3 to 0.6 square meter surface area glass condenser. Bottoms residue was collected below the evaporator body.

### Preparation of MPG Refined

The WFE described above was heated to 180° C. and was charged with 1,850.09 g of Methoxypolyglycol (basic) at a feed pump rate of 17 rpm and a wiper spin rate of 300 rpm at a vacuum of 0.1 torr. Processing was complete in 175 min, with collection of 1,601.13 g of overheads product. The bottoms fraction weighed 200.79 g. The color was less than 50 APHA, and the average molecular weight as determined by GC analysis was 212 g/mole.

### Preparation of BPG Refined

The WFE described above was heated to 200° C. and was charged with 716.74 g of Butoxypolyglycol (basic) at a feed pump rate of 14 rpm and a wiper spin rate of 260 rpm at a vacuum of 0.3 torr. Processing was complete in 105 min, with collection of 490.9 g of overheads product. The bottoms fraction weighed 201.46 g. The color was less than 100 APHA, and the average molecular weight as determined by GC analysis was 262 g/mole.

### Preparation of PolyPnB Refined

The WFE described above was heated to 180° C. and was charged with 917.94 g of PolyPnB Basic at a feed pump rate of 17 rpm and a wiper spin rate of 260 rpm at a vacuum of 0.1 torr. Processing was complete in 95 min, with collection of 755.97 g of overheads product. The bottoms fraction weighed 140.90 g. The color was less than 50 APHA, and the average molecular weight as determined by GC analysis was 292 g/mole.

### Preparation of PolyPnP Refined

The WFE described above was heated to 170° C. and was charged with 1142.50 g of PolyPnP Basic at a feed pump rate of 16 rpm and a wiper spin rate of 260 rpm at a vacuum of 0.1 torr. Processing was complete in 127 min, with collection of 938.2 g of overheads product. The bottoms fraction weighed 187.72 g. The color was less than 50 APHA, and the average molecular weight as determined by GC analysis was 248 g/mole.

### Formulations

### General Procedure for Preparing Flux Remover Formulation

A series of samples of concentrated formulations were prepared including the components described in Table II, e.g., 40 wt % monoethanolamine; 20 wt % ECOSURF™ EH-6; and 40 wt % solvent. Then the concentrated formulations were diluted with water.

TABLE II
Flux Remover Formulations (FRF)

| | FRF1 | FRF2 | FRF3 | FRF4 | FRF5 | FRF6 | FRF7 | FRF8 |
|---|---|---|---|---|---|---|---|---|
| | Inv. | Inv. | Comp. | Comp. | Comp. | Comp. | Comp. | Comp. |
| | Ex. 1 | Ex. 2 | Ex. A | Ex. B | Ex. C | Ex. D | Ex. E | Ex. F |
| Component | (g) | (g) | (g) | (g) | (g) | (g) | (g) | (g) |
| PolyPnP Refined | 1.8 | | | | | | | |
| PolyPnB Refined | | 1.8 | | | | | | |
| DOWANOL ™ DPnB | | | 1.8 | | | | | |
| Hexyl CARBITOL ™ | | | | 1.8 | | | | |
| MPG Refined | | | | | 1.8 | | | |
| BPG Refined | | | | | | 1.8 | | |
| DOWANOL ™ TPnB | | | | | | | 1.8 | |
| Polyglycol P-425 | | | | | | | | 1.8 |
| MEA | 1.8 | 1.8 | 1.8 | 1.8 | 1.8 | 1.8 | 1.8 | 1.8 |
| ECOSURF ™ EH-6 | 0.9 | 0.9 | 0.9 | 0.9 | 0.9 | 0.9 | 0.9 | 0.9 |
| Water | 30 | 30 | 30 | 30 | 30 | 30 | 30 | 30 |

General Procedure for Preparing Rosin Dissolution Formulation

A series of samples of concentrated formulations used for rosin dissolution testing were prepared including the components described in Table III,

A rosin powder and a solvent were mixed in a 20 mL glass bottle. The mixture of rosin powder and solvent in the glass bottle was placed in an oven set at a temperature of 50° C. and heated. Then the mixture in the glass bottle was shaken at 200 rpm for 20 min. Any dissolution of rosin as measured by weight in the solvent was observed with the naked eye and recorded.

TABLE III
Rosin Dissolution Formulations (RDF)

| | RDF1 | RDF2 | RDF3 | RDF4 | RDF5 | RDF6 | RDF7 | RDF8 |
|---|---|---|---|---|---|---|---|---|
| | Inv. | Inv. | Comp. | Comp. | Comp. | Comp. | Comp. | Comp. |
| | Ex. 3 | Ex. 4 | Ex. G | Ex. H | Ex. I | Ex. J | Ex. K | Ex. L |
| Component | (%) | (%) | (%) | (%) | (%) | (%) | (%) | (%) |
| PolyPnP Refined | 100 | | | | | | | |
| PolyPnB Refined | | 100 | | | | | | |
| DOWANOL ™ DPnB | | | 100 | | | | | |
| Hexyl CARBITOL ™ | | | | 100 | | | | |
| MPG Refined | | | | | 100 | | | |
| BPG Refined | | | | | | 100 | | |
| DOWANOL ™ TPnB | | | | | | | 100 | |
| Polyglycol P-425 | | | | | | | | 100 |

### General Procedure for Preparing Photoresist Cleaner Formulation

A series of samples of concentrated formulations used for cleaning photoresist were prepared including the components described in Table IV, e.g., a cleaning formulation was prepared including 20 wt % solvent; 20 wt % monoethanolamine; 0.5 wt % ECOSURF™ EH-6; and 59.5 wt % water having a total weight of 10 g. The formulations were stirred using a magnetic stirrer at 120 RPM and 60° C. The resultant formulations are described in Table IV.

TABLE IV
Photoresist Cleaner Formulations (PCF)

| | PCF1 | PCF2 | PCF3 | PCF4 | PCF5 | PCF6 | PCF7 | PCF8 |
|---|---|---|---|---|---|---|---|---|
| | Inv. | Inv. | Comp. | Comp. | Comp. | Comp. | Comp. | Comp. |
| | Ex. 5 | Ex. 6 | Ex. M | Ex. N | Ex. O | Ex. P | Ex. Q | Ex. R |
| Component | (g) | (g) | (g) | (g) | (g) | (g) | (g) | (g) |
| PolyPnP Refined | 2 | | | | | | | |
| PolyPnB Refined | | 2 | | | | | | |
| DOWANOL ™ DPnB | | | 2 | | | | | |
| Hexyl CARBITOL ™ | | | | 2 | | | | |
| MPG Refined | | | | | 2 | | | |
| BPG Refined | | | | | | 2 | | |
| DOWANOL ™ TPnB | | | | | | | 2 | |
| Polyglycol P-425 | | | | | | | | 2 |
| MEA | 2 | 2 | 2 | 2 | 2 | 2 | 2 | 2 |
| ECOSURF ™ EH-6 | 0.05 | 0.05 | 0.05 | 0.05 | 0.05 | 0.05 | 0.05 | 0.05 |
| Water | 5.95 | 5.95 | 5.95 | 5.95 | 5.95 | 5.95 | 5.95 | 5.95 |

### Tests and Measurements

### GC Analysis

GC (gas chromatography) analysis was carried out on a GC instrument, an Agilent 6890 GC, by injecting 1 μL of sample diluted at approximately 50/50 by volume with methanol onto a 30 m×0.25 mm 0.25 μm film ZB1 column at 100° C. and increasing to 300° C. at 10° C./min. The injector and thermal conductivity detector temperatures were 300° C. A constant helium pressure of 15 psig and a 25:1 split ratio was used. Area percent integration, which was confirmed to represent weight percent composition, was used to express the results.

### Molecular Weights

Average molecular weights were determined using the individual molecular weights of each oligomer along with the amount of each oligomer in the sample as determined by GC analysis.

Average molecular weights as determined by GC analysis were consistent with those measured by hydroxyl titration.

### Hydroxyl Numbers

Hydroxyl numbers were measured as per ASTM D4274. An oven-dried Fisher Porter bottle was cooled with a nitrogen stream and 3.00 grams of sample was weighed into the bottle, taking care not to deposit any sample on the sides of the bottle. The bottle was secured to a ring stand, and 25 mL of phthalic anhydride-pyridine reagent (84 g phthalic anhydride/600 mL anhydrous pyridine) was added. The bottle was sealed with a rubber septum which was secured with a zip tie. This procedure was repeated for two more samples and three blanks (only phthalic anhydride reagent was used for the blanks). All of the bottles were inserted into a bottle rack and placed in a 100° C. water bath for one hour. When the time had elapsed, the rack was removed from the bath and the samples were allowed to cool to room temperature. A bottle was removed from the rack and secured on a stir plate. A stir bar was added and the stirrer turned on to create a vortex. Five drops of alcoholic phenolphthalein solution were added as an indicator. The sample was titrated with 1.00 N NaOH to the light pink endpoint. This procedure was repeated for all of the samples. The hydroxyl number was calculated by:

[[[(mL NaOH blank)−(mL NaOH sample)]×N NaOH solution]/sample weight]×56.1

For mono-protic alcohols such as these glycol ethers, the calculated molecular weight was 1,700/(% OH). Hydroxyl Number was 32.9*(% OH).

### Hansen Solubility Parameters

Hansen solubility parameters (HSP) for butyl-PO and propyl-PO pure components were calculated using the correlations based on the inverse of the molar volume regressions as described in Hansen Solubility Parameters-A User's Handbook, CRC Press, Boca Raton, 1999, 2007.

HSP for the rest of the pure components were calculated using the Yamamoto Molecular Break (YMB) method as described in the commercially available HSPiP program which uses group contribution parameters and SMILES structures. The HSPiP program (4^{th} Edition, 4.1.07) can be found at the website https://usd.swreg.org/com.

### Color

Color was measured using a calibrated HunterLab ColorQuest XT colorimeter according to ASTM D 4890 and was reported using the APHA scale known to those skilled in the art. APHA (American Public Health Association) Color refers to the Hazen scale color or the Platinum/Cobalt (Pt/Co) scale color and is a measure of yellowness, as defined by ASTM D1209.

### Base Concentrations

Base concentrations were measured using a calibrated Mettler Toledo DL70 Autotitrator by dilution of 0.1 g to 5 g of sample in aqueous 2-propanol and titrating with 0.0100 N hydrochloric acid. The results were reported as wt % NaOH.

### Boiling Point Calculation

Boiling points for the various WFE refined products described above were calculated using the LIQACT program available among the CHEMCOMP™ Solvent Modeling Property Service and the area percent compositions obtained from the GC analyses. The LIQACT program uses UNIFAC parameters to estimate activity coefficients for various phase equilibrium calculations. The program can be used to perform calculations for multicomponent mixtures and requires the Antoine constants and the UNIFAC formula for each component in the mixture. When available, Antoine constants were retrieved from the CHEMCOMP™ solvent database and from the PCPROP property databank.

Antoine constants for the higher homologs (e.g., ≥5-9 EO or PO units) were not available and had to be derived in a two-step process. First, the normal boiling point for a component of interest was extrapolated from a plot of boiling points versus EO or PO units for a given glycol ether family (e.g., PnB homologs). This boiling point was then entered into the ANTOINE program (also available from CHEMCOMP™) from which the Antoine constants were retrieved using a single point calculation with the Thomson constrain option and a Trouton constant in accordance with the procedure described in G. W. M. Thomson; “The Antoine Equation for Vapor Pressure Data”, Chem. Rev. (38), p. 1-39, February 1946. The Trouton constant is known as the entropy of vaporization and equals the heat of vaporization in cal/mole (at the boiling point) divided by the boiling point in degrees Kelvin. The various glycol ether homologs were fitted with the following Trouton constants: PnPs (24), Methyls, Ethyls, Hexyls and PolyPGs (26), and PnBs and Butyls (27).

### Boiling Point Measurements

In a typical experiment, 30 mL of WFE product was added to a single neck, 50-mL Kontes Bantam-ware round-bottomed flask equipped with a built-in thermocouple well. A small Teflon® stir bar was added to the flask, which was then secured to the hood lattice with a clamp. A heating mantle was attached to the flask and a magnetic stirring plate was placed beneath the mantle. Control and high limit thermocouples leading from a digital temperature controller were placed between the mantle and the flask. Another thermocouple from a digital temperature meter was placed inside the thermocouple well which contained a few drops of glycerin for heat transfer purposes. A condenser with a drip spout at the bottom of the cooling coils was attached to the flask, and an adapter connected with vacuum tubing to a nitrogen-vacuum line was placed on top of the condenser. The flask was insulated to minimize heat losses. To facilitate pressure control, a Tescom backpressure regulator was placed in the main vacuum line between the vacuum pump and the low pressure (5 psig) nitrogen line which had a pressure relief valve in place to safeguard against over pressurization of the glass equipment. The nitrogen-vacuum line to the condenser was teed-off from the main vacuum line above the nitrogen line. A digital Rosemount gauge was placed at the end of the vacuum line above the tee to the condenser in order to read the actual pressure in the flask. The stirring plate was turned on low speed. Dry ice was added to the vacuum pump trap, and the vacuum pump was turned on. The pressure was adjusted to about 1.0 mmHg while keeping the nitrogen flow off and the Tescom regulator fully open. Water to the condenser was turned on and the flask was heated to about 200° C. (external mantle temperature). When liquid was observed refluxing at the bottom of the condenser, the internal flask temperature and the pressure were recorded. The pressure was then adjusted to the next desired value by opening the nitrogen flow and or adjusting the Tescom regulator in the “increase” direction. The mantle temperature was progressively increased to 250° C., 300° C. and finally 325° C. as the pressure was increased to obtain a range of vapor pressures. A total of 10-20 data points were collected.

The vapor pressure data was fitted to the Antoine equation of log P=A−B/(T+C) using the CHEMCOMP™ Antoine program to retrieve the three Antoine constants and the normal boiling point. The Thomson constrain was used in all vapor-pressure fits.

### Test Results

### General Procedure for Testing Flux Remover Formulation

A solder flux was heated to 80° C., liquified, and spread on the surface of a PCB metal circuit. The liquid solder flux on the surface of the PCB metal circuit froze when the temperature of the flux was reduced to room temperature. A 4.5 g sample of a concentrated formulation of a flux cleaning formulation prepared as described above (formulation: 40 wt % monoethanolamine; 20 wt % ECOSURF™ EH-6; and 40 wt % solvent) was diluted with 30 g of water. The PCB was subsequently immersed in the diluted formulation. For 2 min, ultrasonic (90 Hz) at 45° C. was used to clean the PCB. The results of testing the flux remover formulation are described in Table V.

TABLE V
Test Results for Flux Remover Formulations (FRF)

| | Example No.: | | | | | | | |
|---|---|---|---|---|---|---|---|---|
| | Inv. | Inv. | Comp. | Comp. | Comp. | Comp. | Comp. | Comp. |
| | Ex. 7 | Ex. 8 | Ex. S | Ex. T | Ex. U | Ex. V | Ex. W | Ex. X |
| Formulation | FRF1 | FRF2 | FRF3 | FRF4 | FRF5 | FRF6 | FRF7 | FRF8 |
| Tested: | | | | | | | | |
| Performance: | Clean | Clean | Clean | Clean | Residue | Residue | Clean | Residue |

### General Procedure for Determining “Clean” Versus “Residue”

With reference to Table V, any residue (i.e., solder flux) remaining on the surface of the PCB, after undergoing the cleaning action described above, was observed with the naked eye and the surface area of the PCB covered by residue, if any, after cleaning was noted. If any residue was observed on the PCB metal circuitries, or if ≥0.01% of the total PCB surface area had residue remaining, the PCB was labeled “Residue” to indicate some flux residue was present on the PCB metal circuitries and the cleaning composition did not work sufficiently as a cleaner. On the other hand, if no residue was observed on the PCB metal circuitries, or if <0.01% of the total PCB surface area had residue remaining thereon, the PCB was labeled “Clean” to indicate that no amount of residue or only a very minute amount of residue was present on the PCB metal circuitries.

Alternative to the above-described procedure for determining a clean PCB versus a residue PCB, in some embodiments, a method for distinguishing a “Clean” PCB versus a “Residue” PCB can be done by measuring the period of time needed to completely remove any observable residue from the surface area of a PCB. In this method, a PCB is considered a “Clean” PCB if no residue is observable on the surface of the PCB (i.e., the residue is substantially completely removed from the surface area of a PCB) after the PCB is subjected to the cleaning treatment for a period of ≤120 s in one general embodiment, and from 30 s to 120 s in another embodiment. Conversely, a PCB is considered a “Residue” PCB when the PCB is subjected to the cleaning treatment, and the cleaning treatment takes longer than 120 s to reach a point where no residue is observable on the surface of the PCB (i.e., it takes longer than 120 s to substantially completely remove residue from the surface area of a PCB).

### General Procedure for Testing Rosin Dissolution Formulation

A rosin powder and a solvent were mixed in a 20 mL glass bottle. The mixture of rosin powder and solvent in the glass bottle was placed in an oven set at a temperature of 50° C. and heated for 10 min. Then the mixture in the glass bottle was shaken at 200 rpm for 20 min. Any dissolution of rosin was observed with the naked eye and measured by weight in the solvent and the results were recorded. The results of rosin dissolution are described in Table VI.

TABLE VI
Test Results for Rosin Dissolution Formulations (RDF)

| | Example No.: | | | | | | | |
|---|---|---|---|---|---|---|---|---|
| | Inv. | Inv. | Comp. | Comp. | Comp. | Comp. | Comp. | Comp. |
| | Ex. 9 | Ex. 10 | Ex. Y | Ex. Z | Ex. AA | Ex. BB | Ex. CC | Ex. DD |
| Formulation | RDF1 | RDF2 | RDF3 | RDF4 | RDF5 | RDF6 | RDF7 | RDF8 |
| Tested: | | | | | | | | |
| Solubility*, | 6.40 | 6.30 | 6.37 | 6.25 | 0.97 | 4.78 | 6.32 | 6.25 |
| wt %: | | | | | | | | |

Note for Table VI:
*To determine rosin solubility, rosin was gradually added at 0.01 wt % rosin in the glycol ether. The solubility wt % was the weight of accumulated solids upon solid saturation as visually judged.

### General Procedure for Testing Photoresist Cleaner Formulation

A flexible PCB sheet was placed in a cleaning formulation of 20 wt % solvent; 20 wt % monoethanolamine; 0.5 wt % ECOSURF™ EH-6; and 59.5 wt % water having a total weight of 10 g. The formulation was used for stripping the PCB sheet for 2 min. After 2 min, water was used to rinse the PCB sheet surface; and the PCB sheet was then allowed to dry. Then, the PCB sheet was immersed in a super roughening solution for 10 s. Water was again used to rinse the PCB sheet surface after the PCB sheet was in the roughening solution for 10 s. Then, the PCB sheet was allowed to dry again. Any photoresist residue remaining on the surface of the flexible PCB sheet was observed with the naked eye and recorded. The results of photoresist cleaning are described in Table VII.

TABLE VII
Test Results for Photoresist Cleaner Formulations (PCF)

| | Example No.: | | | | | | | |
|---|---|---|---|---|---|---|---|---|
| | Inv. | Inv. | Comp. | Comp. | Comp. | Comp. | Comp. | Comp. |
| | Ex. 11 | Ex. 12 | Ex. EE | Ex. FF | Ex. GG | Ex. HH | Ex. II | Ex. JJ |
| Formulation | PCF1 | PCF2 | PCF3 | PCF4 | PCF5 | PCF6 | PCF7 | PCF8 |
| Tested: | | | | | | | | |
| Performance: | Clean | Clean | Clean | Residue | Residue | Some | Some | Residue |
| | | | | | | Residue* | Residue* | |

Note for Table VII:
*“Some Residue” means a minor amount of photoresist residue was observed to be present on the PCB; and, the cleaning speed of this composition was not as fast as the other compositions indicated as “Clean”.

With reference to Table VII, the procedure used for determining whether a PCB is considered “Clean”, “Residue” or “Some Residue”, was the same procedure as described above under “General Procedure for Determining “Clean” Versus “Residue”; except that in the Examples of Table VII, a PCB having “Some Residue”, means the residue area of the PCB was in between ≥0.01% and <1% of total PCB surface area. And, “Residue” means the residue area of the PCB was ≥1% of total PCB surface area.

### Discussion of Results

### Flux Remover

The solvents useful for preparing a flux remover composition include, for example, DOWAWNOL™ DPnB, TPnB, Hexyl CARBITOL™, PolyPnP Refined and PolyPnB Refined. DOWANOL™ DPnB and Hexyl CARBITOL™ are industrial standard compounds and are widely used in flux remover applications. Some of the properties of the solvents used in the Examples are described in Table VIII.

[symbol]

One of several advantages of using PolyPnB Refined as the solvent in this flux remover application includes, for example, the solvent has a high boiling point which can increase the temperature of the flux remover formulation which, in turn, accelerates the flux removing speed. The DOWANOL™ TPnB solvent showed the same advantage as the PolyPnB Refined solvent. The solvents: PolyPnB Refined, Hexyl CARBITOL™ and DOWANOL™ TPnB are non-VOC solvents; and thus, these solvents can be used in this flux removing application in some countries which have implemented VOC restriction regulations.

### Rosin Solubility

The solvents useful for solubilizing rosin include, for example, DOWANOL™ DPnB, TPnB, Hexyl CARBITOL™, Polyglycol P-425, PolyPnP Refined and PolyPnB Refined. These solvents have a rosin solubility value of >6 wt %.

### Photoresist Stripper

The solvents useful for stripping photoresist include, for example, DOWANOL™ DPnB, TPnB, PolyPnP Refined and PolyPnB Refined.

One of several advantages of using PolyPnB Refined as a solvent for stripping photoresist from PCBs includes, for example, the solvent has a high boiling point which can increase the temperature of the photoresist stripper formulation which, in turn, accelerates the photoresist removing speed. The DOWANOL™ TPnB solvent showed the same advantage as the PolyPnB Refined solvent. The solvents: PolyPnB Refined, Hexyl CARBITOL™ and DOWANOL™ TPnB are non-VOC solvents; and thus, these solvents can be used in this photoresist removing application in some countries which have implemented VOC restriction regulations.

The solvents used for flux removing and photoresist stripping; and having a lower polarity Hansen solubility parameter, show a more effective performance than solvents having a high Hansen solubility parameter. Solvents having a lower hydrogen-bonding Hansen solubility parameter can also improve the performance of the solvents. The rosin solubility values of the solvents are also highly related to the two parameters of polarity Hansen solubility parameter and hydrogen-bonding Hansen solubility parameter. The comparisons of the solvents used in the Examples are described in Table VIII.

The solvent DOWANOL™ DPnB is considered a VOC material; however, the performance DOWANOL™ DPnB in the present invention is very good. On the other hand, the performance of the solvent DOWANOL™ TPnB, which has a lower hydroxyl number, water miscibility, and formulation stability, is not as good.

The solvent Polyglycol P-425 has a viscosity that is quite high which reduces the interaction of the solute surface with the solvent. Thus, rosin dissolution evaluation, for the solvent Polyglycol P-425, is static and shows good results. However, in evaluating the dynamic processes of flux removing and photoresist stripping, the performance of Polyglycol P-425 is negative because Polyglycol P-425 contains two hydroxyl groups in one molecule which shows higher polarity; and as a consequence of solvent having high polarity, the solvent is not as good for dissolving flux or photoresist.

What is claimed is:

1. A glycol ether-containing water-based composition for use as a cleaning formulation during the manufacturing process of printed circuit boards, the composition comprising:
(a) at least one glycol ether having a boiling point of greater than 240° C.; and a VOC content, in terms of vapor pressure, of less than 10 Pa at 20° C.;
(b) at least one organic amine;
(c) at least one surfactant; and
(d) water.

2. The composition of claim 1, wherein the boiling point at 101.3 kilopascals pressure of the at least one glycol ether is from greater than 240° C. to 350° C.

3. The composition of claim 1, wherein the average molecular weight (Mw) of the at least one glycol ether is from 170 to 550.

4. The composition of claim 1, wherein the hydroxyl number of the at least one glycol ether is from 220 to 320.

5. The composition of claim 1, wherein the dispersion Hansen solubility parameter of the at least one glycol ether is from 13.0 J/cc^{1/2} to 15.5 J/cc^{1/2}.

6. The composition of claim 1, wherein the polarity Hansen solubility parameter of the at least one glycol ether is from 0.5 J/cc^{1/2} to 3.0 J/cc^{1/2}.

7. The composition of claim 1, wherein the hydrogen-bonding Hansen solubility parameter of the at least one glycol ether is from 6.5 J/cc^{1/2} to 8.5 J/cc^{1/2}.

8. The composition of claim 1, wherein the composition comprises from 20 weight-percent to 70 weight-percent of the at least one glycol ether; from 1 weight-percent to 15 weight-percent of the at least one organic amine; from 0.01 weight-percent to 10 weight-percent of the at least one surfactant; and the remainder water; each based on the total weight of the composition.

9. A process for preparing a glycol ether-containing water-based composition comprising mixing:
(a) at least one glycol ether having a boiling point of greater than 240° C.; and a VOC content, in terms of vapor pressure, of less than 10 Pa at 20° C.;
(b) at least one organic amine;
(c) at least one surfactant; and
(d) water; to form the water-based composition.

10. The process of claim 9, wherein the composition is used as a cleaning formulation for cleaning printed circuit boards during the manufacture of printed circuit boards.

11. A process for cleaning a substrate comprising the steps of:
(A) providing a substrate to be cleaned; wherein the substrate contains a first amount of contaminants deposited thereon;
(B) contacting the substrate of step (A) with the water-based composition of claim 1 for a predetermined period of time; wherein, after the contacting step (B), the first amount of contaminants on the substrate is reduced to a second reduced amount of contaminants to form a cleaned substrate; wherein the second reduced amount of contaminants on the cleaned substrate of step (B) covers less than 0.01 percent of the surface area of the substrate and is lower than the first amount of contaminants on the substrate of step (A); and
(C) optionally, rinsing the cleaned substrate from step (B) with clean or pure water.

12. The process of claim 11, wherein the period of time of the contacting step (B) for removing contaminants from the substrate, under ultrasonic cleaning conditions (90 Hz) at 45° C., is less than 120 seconds.

13. The process of claim 11, wherein the period of time of the contacting step (B), at 25° C., is less than 120 seconds.

14. The process of claim 11, wherein the substrate is a printed circuit board.
